(19) United States
(12) Patent Application Publication
(10) Pub. No.: US 2024/0159799 A1
(43) Pub. Date: May 16, 2024

(54) MULTI-INSTRUMENT DEVICE BASED ON PARTIAL RECONFIGURATION FPGA

(71) Applicant: LIQUID INSTRUMENTS PTY. LTD., Lyneham (AU)

(72) Inventors: Daniel Anthony SHADDOCK, Lyneham (AU); Danielle Marie RAWLES WUCHENICH, Woodside, CA (US); Benjamin Paul COUGHLAN, Lyneham (AU); Timothy Tien-Yue LAM, Lyneham (AU)

(21) Appl. No.: 18/282,193

(22) PCT Filed: Mar. 15, 2022
(86) PCT No.: PCT/US2022/020367

§ 371 Date: Sep. 14, 2023

Related U.S. Application Data
(60) Provisional application No. 63/161,348, filed on Mar. 15, 2021.

(51) Int. Cl. G01R 15/12; H03M 1/00

(52) U.S. Cl. CPC G01R 15/12; H03M 1/001

(57) ABSTRACT

This disclosure provides systems, methods, and apparatus for implementing multiple test and measurement devices into a single multi-instrument device (102). The device can include at least one field programmable gate array, FPGA (112), that allows partial reconfiguration. One or more dynamic reconfigurable portions of the FPGA can be configured to function as one or more test and measurement devices. The device can provide outputs of each of the test and measurement instruments to a client device, which can display the outputs to a user. The device can be reconfigured by loading bitstreams (122,136) associated with the desired test and measurement device. The bitstreams can be loaded from the client device (104), a server (106), or from a memory storage unit (114) of the device itself.

### CROSS-REFERENCE TO RELATED APPLICATIONS

This application claims the benefit of priority of U.S. Provisional Application No. 63/161,348, filed Mar. 15, 2021, entitled “Multi-Instrument Device Based on Partial Reconfiguration FPGA,” the contents of which are incorporated herein in their entirety.

### TECHNICAL FIELD

This disclosure relates to the field of electronic test and instruments, and in particular to multi-instrument devices.

### DESCRIPTION OF THE RELATED TECHNOLOGY

Test and measuring instruments are commonly used in electronic device development. Typically, the test and measuring instruments are discrete devices in discrete packages. In some instances, modular hardware devices embodying a test or measuring instrument can be removably installed in a device to modify the functionality of the device and thereby allowing a single device to provide multiple testing and instrumental functionality. Some devices support software-based test and instruments that can be selectively installed on a hardware platform to allow even more flexibility in the functionality of the device.

### SUMMARY

In one aspect, a system includes a multi-instrument device and a server. The multi-instrument device includes a static reconfigurable portion, a plurality of dynamic reconfigurable portions, each of the plurality of dynamic reconfigurable portions configured as a test and measurement device, and a controller, coupled with the static reconfigurable portion and the plurality of dynamic reconfigurable portions. The controller is configured to process at least one bitstream to reconfigure at least one of the plurality of dynamic reconfigurable portions as a test and measurement device. The server includes memory configured to store the at least one bitstream, and at least one processor configured to receive a request for providing the at least one bitstream, and responsive to the request, retrieve the at least one bitstream from the memory and transmit the at least one bitstream for delivery to the multi-instrument device.

In some embodiments, the at least one processor is configured to receive the request for providing the at least one bitstream from a user device in communication with the multi-instrument device. In some embodiments, the request for providing the at least one bitstream is a first request, where the at least one bitstream is a first at least one bitstream, where the at least one processor is configured to receive a second request for providing a second at least one bitstream, and responsive to the second request, retrieve a second at least one bitstream from the memory and transmit the second at least one bitstream to the multi-instrument device. The controller is configured to based on the second at least one bitstream, reconfigure at least one of the plurality of dynamic reconfigurable portions from one test and measurement device to another test and measurement device. In some embodiments, the multi-instrument device further includes a data interface configured to output a data stream associated with each of the plurality of dynamic reconfigurable portions to a separate physical output port.

In some embodiments, the multi-instrument device further includes a data interface configured to output a data stream associated with each of the plurality of dynamic reconfigurable portions to at least one of a serial data port or a network port. In some embodiments, the static reconfigurable portion includes at least one data bus configured to carry signals from at least one dynamic reconfigurable portion of the plurality of dynamic reconfigurable portions to at least one another dynamic reconfigurable portion of the plurality of dynamic reconfigurable portions. In some embodiments, the static reconfigurable portion includes at least one multiplexer having inputs coupled with outputs of the plurality of dynamic reconfigurable portions, and at least one output coupled with an input of at least one dynamic reconfigurable portion of the plurality of dynamic reconfigurable portions, where the controller is configured to control the multiplexer to allow at least one of the outputs of the plurality of dynamic reconfigurable portions to be provided to the input of the at least one dynamic reconfigurable portion of the plurality of dynamic reconfigurable portions.

In some embodiments, at least one output of the plurality of dynamic reconfigurable portions provides a data stream representing a quantized near real-time analog signal. In some embodiments, the static reconfigurable portion includes at least one channel buffer coupled with each dynamic reconfigurable portion of the plurality of dynamic reconfigurable portions, each of the at least one channel buffer coupled with a channel output of a corresponding one of the plurality of dynamic reconfigurable portions, the at least one channel buffer configured to buffer a channel data stream output by the channel output and provide a buffered channel data stream to a memory. In some embodiments, the controller is configured to process the buffered channel data stored in the memory to generate an output channel buffer data, and provide the output channel buffer data to one or more output ports of the multi-instrument device. In some embodiments, the output channel buffer data is an image frame.

In some embodiments, channel data streams of at least one channel buffer coupled with each dynamic reconfigurable portion of the plurality of dynamic reconfigurable portions are stored into the memory. In some embodiments, the controller is configured to output the channel data streams to the one or more output ports of the multi-instrument device. In some embodiments, at least one dynamic reconfigurable portion of the plurality of dynamic reconfigurable portions includes at least one control register coupled with the controller via a control bus, and at least one memory unit coupled with the controller via the control bus, where the at least one control register and the at least one memory unit store configuration data received from the controller and where the at least one memory unit is larger in size than the at least one control register.

In some embodiments, at least one dynamic reconfigurable portion of the plurality of dynamic reconfigurable portions includes at least one multiplexer, at least one input of which is coupled with data stream outputs of one or more other dynamic reconfigurable portions of the plurality of dynamic reconfigurable portions, and at least one processor, at least one input of which is coupled with at least output of the at least one multiplexer. In some embodiments, the system further includes the user device communicably coupled with the multi-instrument device and communicably coupled with the server, the user device configured to send the request to the server for providing the at least one bitstream, receive a transmission from the server including the at least one bitstream, and transmit the at least one bitstream to the multi-instrument device. In some embodiments, the static reconfigurable portion includes at least one analog-to-digital converter (ADC) and at least one digital-to-analog converter (DAC), where each of the plurality of dynamic reconfigurable portions is selectively coupled with the at least one ADC and selectively coupled with the at least one DAC.

In another aspect, a multi-instrument device includes a static reconfigurable portion, and a plurality of dynamic reconfigurable portions, at least one of the plurality of dynamic reconfigurable portions is configured as a test and measurement device, and a controller, coupled with the static reconfigurable portion and the plurality of dynamic reconfigurable portions, the controller configured to reconfigure at least one of the plurality of dynamic reconfigurable portions as a test and measurement device based on at least one bitstream received over a data interface and reconfigure the static reconfigurable portion to provide data streams generated by each of the plurality of dynamic reconfigurable portions at a plurality of output ports.

In some embodiments, the plurality of output ports include a plurality of physical output ports, and where each physical output port of the plurality of physical output ports is selectively coupled to any one of the plurality of dynamic reconfigurable portions. In some embodiments, the multi-instrument device further includes a plurality of input ports, and a plurality of analog-to-digital converters (ADCs) coupled with the plurality of input ports, where the static reconfigurable portion includes at least one input bus coupled with the plurality of ADCs and configured to selectively provide digital signals from each of the plurality of ADCs to each of the plurality of dynamic reconfigurable portions. In some embodiments, the multi-instrument device further includes a plurality of output ports, and a plurality of digital-to-analog converters (DACs) coupled with the plurality of output ports, where the static reconfigurable portion includes at least one output bus coupled with the plurality of DACs and configured to selectively provide output signals from each of the plurality of dynamic reconfigurable portions to each of the plurality of DACs.

In some embodiments, the at least one bitstream is a first at least one bitstream, where the at least one controller is configured to receive a second at least one bitstream over the data interface, and reconfigure the at least one of the plurality of dynamic reconfigurable portions from one test and measurement device to another test and measurement device based on the second at least one bitstream. In some embodiments, the multi-instrument device further includes an output interface configured to output a data stream associated with each of the plurality of dynamic reconfigurable portions to a separate physical output port. In some embodiments, the multi-instrument device further includes a network interface configured to output a data stream associated with each of the plurality of dynamic reconfigurable portions to at least one of a serial data port or a network port. In some embodiments, the static reconfigurable portion includes at least one data bus configured to carry signals from at least one dynamic reconfigurable portion of the plurality of dynamic reconfigurable portions to at least one another dynamic reconfigurable portion of the plurality of dynamic reconfigurable portions.

In some embodiments, the static reconfigurable portion includes at least one multiplexer having inputs coupled with outputs of the plurality of dynamic reconfigurable portions, and at least one output coupled with an input of at least one dynamic reconfigurable portion of the plurality of dynamic reconfigurable portions, where the controller is configured to control the multiplexer to allow at least one of the outputs of the plurality of dynamic reconfigurable portions to be provided to the input of the at least one dynamic reconfigurable portion of the plurality of dynamic reconfigurable portions. In some embodiments, at least one output of the plurality of dynamic reconfigurable portions provides a data stream representing a quantized near real-time analog signal. In some embodiments, the static reconfigurable portion includes at least one channel buffer coupled with each dynamic reconfigurable portion of the plurality of dynamic reconfigurable portions, each of the at least one channel buffer coupled with a channel output of a corresponding one of the plurality of dynamic reconfigurable portions, the at least one channel buffer configured to buffer a channel data stream output by the channel output and provide a buffered channel data stream to a memory.

In some embodiments, the controller is configured to process the buffered channel data stored in the memory to generate an output channel buffer data, and provide the output channel buffer data to one or more output ports of the multi-instrument device. In some embodiments, the output channel buffer data is an image frame. In some embodiments, channel data streams of at least one channel buffer coupled with each dynamic reconfigurable portion of the plurality of dynamic reconfigurable portions are stored into the memory. In some embodiments, the controller is configured to output the channel data streams to one or more output ports of the multi-instrument device. In some embodiments, the at least one dynamic reconfigurable portion of the plurality of dynamic reconfigurable portions includes at least one control register coupled with the controller via a control bus, and at least one memory unit coupled with the controller via the control bus, where the at least one control register and the at least one memory unit store configuration data received from the controller and where the at least one memory unit is larger in size than the at least one control register.

In some embodiments, the at least one dynamic reconfigurable portion of the plurality of dynamic reconfigurable portions includes at least one multiplexer, at least one input of which is coupled with data stream outputs of one or more other dynamic reconfigurable portions of the plurality of dynamic reconfigurable portions, and at least one processor, at least one input of which is coupled with at least output of the at least one multiplexer. In some embodiments, the multi-instrument device further includes a memory interface coupled with a memory storage, where the controller is configured to access the at least one bitstream from the memory storage over the memory interface. In some embodiments, the controller is configured to receive instructions for reconfiguring the at least one of the plurality of dynamic reconfigurable portions from a user device via an interface, and responsive to the receipt of the instructions, access the at least on bitstream from the memory storage over the memory interface.

In some embodiments, the multi-instrument device further includes at least one digital input port, where the static reconfigurable portion includes at least one input bus coupled with the at least one digital input port and configured to selectively provide digital signals from each of the at least one digital input port to each of the plurality of dynamic reconfigurable portions. In some embodiments, the multi-instrument device further includes at least one digital output port, where the static reconfigurable portion includes at least one output bus coupled with the at least one digital output and configured to selectively provide output signals from each of the plurality of dynamic reconfigurable portions to each of the at least one digital output port.

### BRIEF DESCRIPTION OF THE DRAWINGS

FIG. 1 shows an example system including a multi-instrument device.

FIGS. 2-4 illustrate various ways in which the system communicates bitstreams to the multi-instrument device.

FIG. 5 shows a block diagram of a portion of an example multi-instrument device.

FIG. 6 shows an example block diagram of the first dynamic reconfigurable portion shown in FIG. 5.

Like reference numbers and designations in the various drawings indicate like elements.

### DETAILED DESCRIPTION

The various concepts introduced above and discussed in greater detail below may be implemented in any of numerous ways, as the described concepts are not limited to any particular manner of implementation. Examples of specific implementations and applications are provided primarily for illustrative purposes.

Test and measurement instruments are an essential component of electronic device testing and manufacturing. Testing of even a simple electronic device can involve several instruments such as oscilloscopes, waveform generators, spectrum analyzers, filters, etc. The number of instruments can get even larger when the complexity of the electronic devices to be tested increases. As a result, the cost and portability of such as system can be prohibitive.

Field programmable gate arrays (FPGAs) provide the ability to program functionality into the FPGA in the field. In particular, the FPGAs can be configured to operate as a first test and measurement device at one time and can be reconfigured to operate as a second test and measurement device at a later time. Some FPGAs include partial reconfiguration portions that allow portions of the FPGA to be reconfigured during runtime. Such FPGAs can be configured to operate a plurality of test and measurement devices. Moreover, one or more of the test and measurement devices can be dynamically reconfigured to operate as a different test and measurement device when desired.

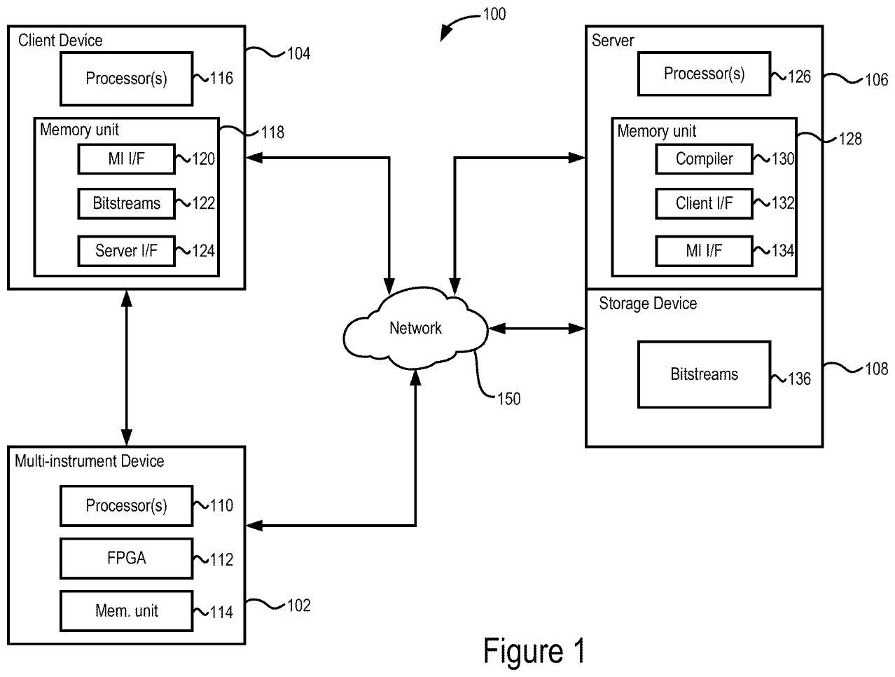

FIG. 1 shows an example system 100 including a multi-instrument device 102. The system 100 can include the multi-instrument device 102, a client device 104, server 106, and a remote storage device 108. The multi-instrument device 102, which is discussed in further detail below, can include one or more processors 110 (also referred to as “controllers”), one or more FPGAs 112, and one or more memory units 114. The multi-instrument device 102 can accommodate multiple test instruments, measuring instruments, and data and signal processing units in the one or more FPGAs 112. The client device 104 can include a mobile device, such as, for example, a tablet, a laptop, a smartphone, etc.; a desktop computer, a personal computer, or any computing device. The client device 104 can include one or more processors 116 and at least one memory unit 118, which can include one or more programs or applications such as, for example, a multi-instrument device interface program 120, a set of set of bitstreams 122, and a server interface program 124. The programs in the at least one memory unit 118 can be executed by the one or more processors 116. The multi-instrument device interface program 120 can interface with the multi-instrument device 102 and can send and receive data between the client device 104 and the multi-instrument device 102. The server interface program 124 can interface with the server 106, i.e., can communicate with the server 106 to request applications, programs, and bitstreams, such as, for example, the set of set of bitstreams 122, which can include configuration information of the one or more FPGAs 112.

The server 106 can include one or more processors 126, and at least one memory unit 128. The at least one memory unit 128 can include one or more programs or applications such as, for example, a compiler program 130, a client device interface program 132, and a multi-instrument device interface program 134. The compiler program 130 can compile FPGA configurations described in hardware description languages such as, for example, Verilog, VHDL, etc., to generate corresponding bitstreams that can be loaded onto an FPGA to configure the FPGA. The client device interface program 132 can communicate with the server interface program 124 on the client device 104 to communicate programs, applications, and data between the client device 104 and the server 106. The multi-instrument interface program 134 can communicate with a corresponding program (not shown in FIG. 1) to communicate programs, applications, and data between the server 106 and the multi-instrument device 102. The communication can include, for example, a set of bitstreams for configuring the FPGA 112. The storage device 108 can store, for example a set of bitstreams 136 that can be communicated to the client device 104 and/or the multi-instrument device 102. In some instances, the server 106 can store compiled bitstreams in the storage device 108 or retrieve stored bitstreams in the storage device 108 and provide the bitstreams to the multi-instrument device 102 or the client device 104.

The multi-instrument device 102, the client device 104, the server 106 and the storage device 108 can communicate over a network 150, which can include one or more of packet-based communication networks, local area networks, wide area networks, public/private networks, the Internet, etc. In some instances, the multi-instrument device 102 and the client device 104 can directly communicate with the storage device 108. In some instances, the server 106 and the storage device 108 can be located in the cloud and can be implemented over a distributed set of servers or storage devices.

The multi-instrument device 102 can support several test instruments, measurement instruments, and signal generators, etc. The one or more FPGAs 112 provide the ability for the multi-instrument device 102 to dynamically assign instruments to the one or more FPGAs 112. In particular, the one or more FPGAs 112 can support partial reconfiguration (PR), which allows dynamic changing of functional blocks in an active design, while the rest of the FPGA continues to operate. PR can be used to change hardware modules at different times during runtime of an FPGA, thereby permitting large complex designs to fit on a relatively smaller FPGAs. At least one of the one or more FPGAs 112 can support PR and can be divided into static reconfigurable portions and dynamic reconfigurable portions. A full bitstream can correspond to configuring the entire FPGA, however, a partial bitstream corresponding to the dynamic configurable portions can be loaded into the FPGA to reconfigure and change the functionality of the dynamic reconfigurable portions. For example, after the one or more processors 110 loads the full bitstream into the one or more FPGAs 112, the one or more processors 110 can load a partial bitstream to change the functionality of a dynamic reconfigurable portion from say, for example, an oscilloscope to a spectrum analyzer. The static reconfigurable portion and other dynamic reconfigurable portions that do not correspond to the partial bitstream can continue to operate while the bitstream is loaded into the target dynamic reconfigurable portion. The one or more FPGAs 112 can be implemented using PR FPGAs such as, for example, Xilinx 7 Series and Zynq FPGA devices.

In some instances, the compiler program 130 in the server 106 can compile the hardware description language description of the static reconfigurable portions and the dynamic reconfigurable portion to generate the full bitstream and the partial bitstream. The compiler program 130 can be specific to the one or more FPGAs 112. For example, the Vivado Design Suite can be used to generate the bitstreams. With respect to the dynamic reconfigurable portions, each bitstream can correspond to a different test and measurement device (the term “test and measurement device” hereinafter is not limited to test and measurement devices, but can also refer to components such as amplifiers, arbitrary waveform generators, proportional-integral-derivative (PID) controller, frequency response analyzer, phasemeter, oscilloscope, spectrum analyzer, digital filter, waveform generator, data logger, filter builder, etc.). A user can load a bitstream associated with a first test and measurement device into the one or more FPGAs 112. If the user desires to operate a different test and measurement device, the user can load a bitstream associated with second test and measurement device into the one or more FPGAs 112. The compiler program 130 can compile the hardware descriptions of various test and measurement devices and store the bitstreams as the set of set of bitstreams 136. While FIG. 1 shows the compiler program 130 located at the server 106, the compiler program 130 or another compiler program can also be located at the client device 104. Because the compilation of the hardware description of the various test and measurement devices can be substantially costly in terms of time and computing resources, the compilation process can be carried out by the server 106 a priori.

The client device 104 can include the multi-instrument device interface program 120 that can not only control the multi-instrument device 102 but can also receive measurement data from the multi-instrument device 102. In other words, the client device 104 can function as a control center for the multi-instrument device 102. As the multi-instrument device 102 may not include a display screen or graphical user interface, the display screen and graphical user interface of the client device 104 can be used to indirectly control the operation of the multi-instrument device 102. The multi-instrument device interface program 120 can allow the user to select the type of instruments that the user would like to implement on the one or more FPGAs 112. To that end, the client device 104 can be used to facilitate the loading of the bitstream corresponding to the desired instruments into the one or more FPGAs 112.

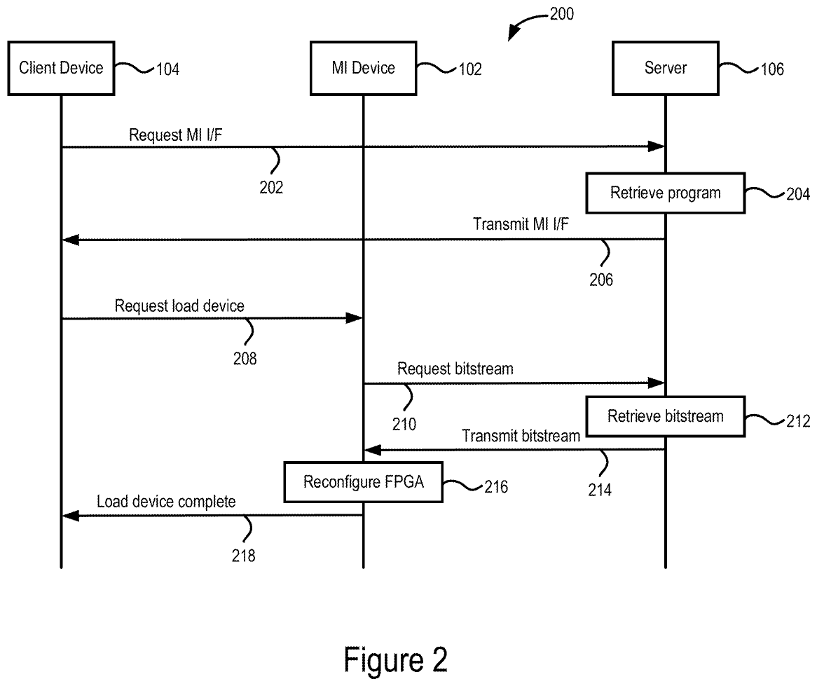

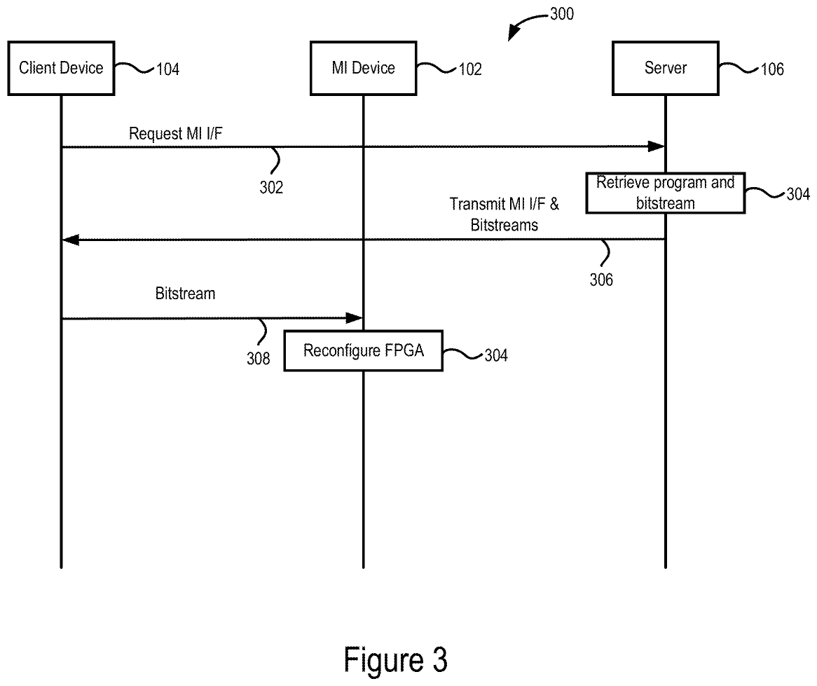

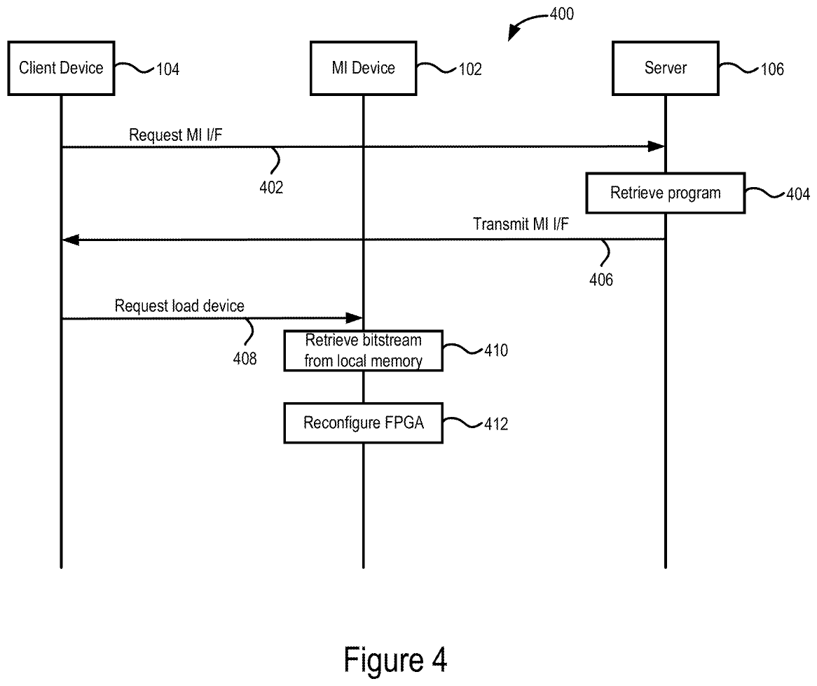

The set of bitstreams 136 can be provided to the multi-instrument device 102 in several ways. In some instances, the client device 104 can download the set of bitstreams 136 from the storage device 108 and provide the set of bitstreams 136 to the multi-instrument device 102. In some other instances, the multi-instrument device 102 can directly download the set of bitstreams 136 from the storage device 108. In yet other instances, the set of bitstreams 136 can be preloaded in the one or more memory units 114 of the multi-instrument device 102, which the one or more processors 110 can access and load into the one or more FPGAs 112. FIGS. 2-4 illustrate various ways in which the system communicates bitstreams to the multi-instrument device 102. Specifically, FIG. 2 illustrates a flow diagram of an example process in which the multi-instrument device 102 requests the set of bitstreams from the server 106; FIG. 3 illustrates a flow diagram of an example process in which the client device 104 requests the bitstream from the server 106 and provides the bitstream to the multi-instrument device 102; and FIG. 4 illustrates a flow diagram of an example process in which the multi-instrument device 102 retrieves and loads the bitstream from a local memory unit.

Referring to FIG. 2, the process 200 includes the client device 104 sending a request 202 for the multi-instrument device interface program 120 to the server 106. In some examples, the multi-instrument device interface program 120 can be an application (e.g., an app for a tablet client device 104) that can be downloaded from an application server (e.g., Apple App store, Google Play App store, etc.). In such instances, the server 106 can include the application server from which the application can be downloaded. The server 106 generally can include one or more servers that can process requests for the multi-instrument device interface program 120. For example, the server 106 can include a cloud server, a file server, a web server, a database server, a proxy server, etc., each of which can be implemented on one or more processors and can be integrated or distributed over a network. Upon receiving the request 202, the server 106 can retrieve 204 the multi-instrument device interface program 120 from a memory storage unit. The server 106 can then transmit 206 the retrieved multi-instrument device interface program 120 to the client device 104. It should be noted that the server 106 can be implemented as more than one server such as, for example, a set of distributed servers, which can communicate with each other to retrieve the multi-instrument device interface program 120 from remote memory storage units.

The multi-instrument device interface program 120 running on the client device 104 can request 208 the multi-instrument device 102 to load a desired test and measurement device in one or more of the dynamic reconfigurable portions of the one or more FPGAs 112. In some instances, the request 208 can be sent to the multi-instrument device 102 when the multi-instrument device 102 is initialized for the first time and does not have any test and measurement devices loaded in the one or more FPGAs 112. In some other instances, the request 208 can be sent to the multi-instrument device 102 when the user requests to replace a test and measurement device currently loaded in the one or more FPGAs 112. The multi-instrument device 102 can transmit a request 210 for the bitstream associated with the requested test and measurement device to the server 106. It should be noted that the request 210 for the bitstream may be transmitted to a device that is different from the device that provides the multi-instrument device interface program 120 to the client device 104. For example, the request 210 for the bitstream could be sent to a cloud storage device, separate from the server 106, that stores the bitstreams associated with various test and measurement devices that can be loaded onto the one or more FPGAs 112. The request 210 could also be sent directly to the storage device 108 instead of to the server 106. In response to receiving the request 210 for the bitstream, the server 106 can access the storage device 108 to retrieve 212 the requested bitstream. The server 106 can transmit 214 the requested bitstream to the multi-instrument device 102. The multi-instrument device 102, upon receiving the bitstream, can reconfigure 216 the one or more FPGAs 112 load the bitstream into the one or more FPGAs 112. The multi-instrument device 102 also can send a notification 218 to the client device 104 indicating that the requested test and measurement device has been loaded.

FIG. 3 illustrates a flow diagram of an example process 300 in which the client device 104 requests the bitstream from the server 106 and provides the bitstream to the multi-instrument device 102. The client device 104 can request 302 to download the multi-instrument device interface program 120 form the server 106. In response to receiving the request, the server 106 can retrieve 304 the multi-instrument device interface program 120 from a memory storage unit. However, in this instance, the server 106 may also retrieve 304 a set of bitstreams corresponding to a set of test and measurement devices. The server 106 can then transmit both the multi-instrument device interface program 120 and the set of bitstreams to the client device 104. The server 106 can transmit the set of bitstreams in the same package as the multi-instrument device interface program 120 requested by the client device 104. As an example, when the client device 104 accesses an application server (such as, for example, the Apple App Store or the Google Play App store), to download the multi-instrument device interface program 120, the server 106 can also include a set of bitstreams in the download. By downloading the set of bitstreams along with the multi-instrument device interface program 120, the client device can load into the multi-instrument device 102 the bitstream corresponding to the desired test and measurement device without having to again access the server 106 over the network 150 to download the bitstream. During initial configuration or during reconfiguration of the multi-instrument device 102, the client device 104 can transmit 308 the desired bitstreams to the multi-instrument device 102 to load into the one or more FPGAs 112. After receiving the bitstreams from the client device 104, the multi-instrument device 102 can load the bitstreams into the one or more FPGAs 112 and configure the one or more FPGAs 112 with the desired test and measurement devices. If the user decides to replace one or more test and measurement devices currently running on the one or more FPGAs 112, the user can select the corresponding bitstream from the previously downloaded set of bitstreams and transmit the bitstream to the multi-instrument device 102. If the bitstream corresponding to the desired test and measurement device is not included in the initially downloaded set of bitstreams, the client device 104 can request the specific bitstream from the server 106 or instruct the multi-instrument device 102 to request the bitstream from the server 106.

FIG. 4 illustrates a flow diagram of an example process 400 in which the multi-instrument device 102 retrieves and loads the bitstream from a local memory unit. In particular, the client device 104 can request 402 the multi-instrument device interface program 120 form the server 106 in the manner similar to that discussed above in relation to request 202 shown in FIG. 2. The server 106 can retrieve 404 the multi-instrument device interface program 120 and transmit 406 the multi-instrument device interface program 120 to the client device in a manner similar to that discussed above in relation to the retrieval 204 and transmission 206 shown in FIG. 2. The client device 104 can request the multi-instrument device 102 to load a test and measurement device into the one or more FPGAs 112. However, the client device 104 may not transmit the bitstream corresponding to the requested test and measurement device to the multi-instrument device 102. Instead, the multi-instrument device 102 can retrieve 410 the bitstream corresponding to the requested test and measurement device from a local memory unit such as the one or more memory units 114 shown in FIG. 1. The multi-instrument device 102 can then proceed to reconfigure the one or more FPGAs 112 by loading the retrieved bitstream into the one or more FPGAs 112. The multi-instrument device 102 can select the appropriate bitstream from a set of bitstreams already stored in the local memory. In some examples, the multi-instrument device 102 can come pre-loaded with the set of bitstreams when it is sold or shipped to the user. In some examples, the set of bitstreams can be loaded into the local memory of the multi-instrument device 102 during an initial configuration procedure, in which the set of bitstreams can be loaded by the client device 104 or can be accessed from the server 106 (as shown in FIG. 2). Storing the set of bitstreams in the local memory of the multi-instrument device 102 can alleviate the need to communicate with the server 106 over the network. This can be advantageous in scenarios where network connectivity is unreliable or unavailable. In addition, by avoiding communication with the server 106, time delays associated with requesting and downloading the set of bitstreams from the server 106 can avoided, thereby improving the time needed to reconfigure the one or more FPGAs 112 with a new test and measurement device.

In each of the above processes discussed in relation to FIGS. 2-4, the client device 104 or the multi-instrument device 102 contribute in loading combined bitstreams into the FPGA. For example, the client device 104 or the multi-instrument device 102 can load partial bitstreams into the one or more FPGAs 112 along with a request for which combinations of the partial bitstreams are to be loaded. The one or more FPGAs 112 can load the partial bitstreams in the requested combination in sequence, thereby combining the partial bitstreams in the requested manner. Each of the partial bitstreams can correspond to a particular functionality or instrument. By combining the bitstreams in the requested combination, the one or more FPGAs 112 can create combined functionality by way of loading the partial bitstreams.

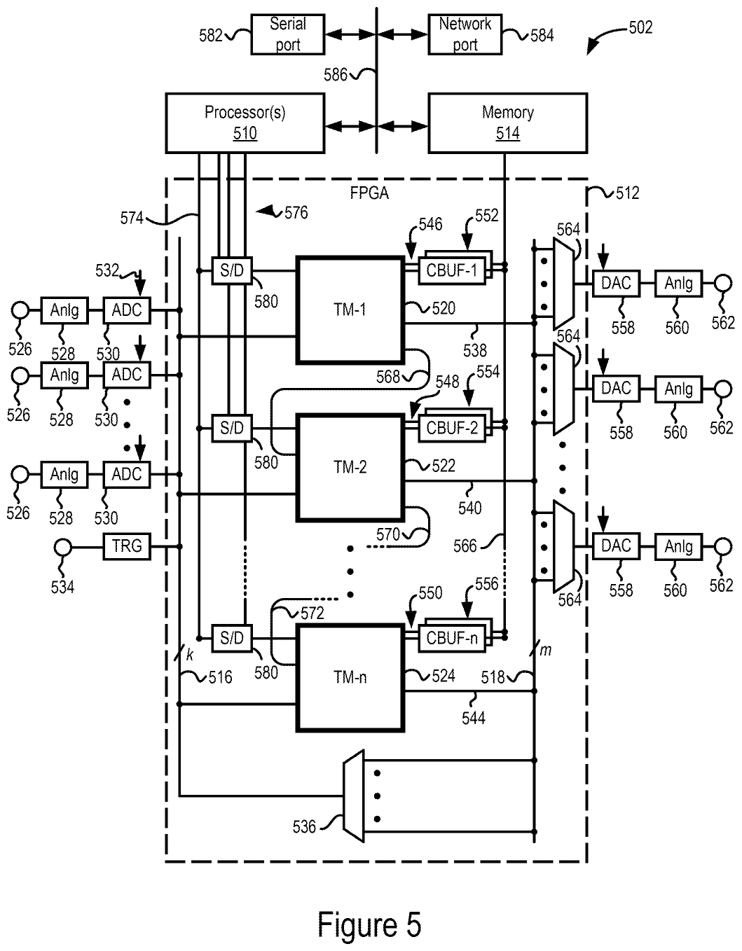

FIG. 5 shows a block diagram of a portion of an example multi-instrument device 502. The multi-instrument device 502 can be used to implement the multi-instrument device 102 discussed above. The multi-instrument device 502 includes one or more processors 510, an FPGA 512, and one or more memory units 514. The one or more processors 510 can be used to implement the one or more processors 110 shown in FIG. 1, the FPGA 512 can be used to implement one or more of the one or more FPGAs 112 shown in FIG. 1, and the memory unit 514 can be used to implement the one or more memory units 114. The one or more processors 510 can include a controller, a microprocessor, a multi-core processor, or any device that can be configured to execute a set of instructions associate with one or more programs. For example, the one or more processors 510 can include a single-core or multi-core ARM Cortex-A9 or Cortex-A53 processors.

The one or more memory units 514 can include volatile as well as non-volatile memory. For example, the one or more memory units 514 can include volatile memory such as DDR SDRAM or any other type of RAM. The non-volatile memory can include ROM, EEPROMs, flash drive, memory cards (e.g., SD cards), etc. The one or more processors 510 also can include memory units such as cache memory and additional volatile secondary memory. The one or more processors 510 and the one or more memory units 514 can be configured to communicate with each other, such that the one or more processors 510 can retrieve instructions from and store data to the one or more memory units 514.

The FPGA 512 can be communicably coupled with the one or more processors 510 and the one or more memory units 514. The FPGA 512 can be one of many FPGAs in the multi-instrument device 502. In some examples, the number of FPGAs in the multi-instrument device 502 can be equal to or greater than the number of channel inputs, where at least one of the FPGAs can be used to consolidate the outputs of the other FPGAs. As mentioned above, the multi-instrument device 102 can include partially reconfigurable FPGAs. The partially reconfigurable FPGAs include static reconfigurable portions and dynamic reconfigurable portions. The FPGA 512 shown in FIG. 5 can include a plurality of dynamic reconfigurable portions: a first dynamic reconfigurable portion 520, a second dynamic reconfigurable portion 522, and an n-th dynamic reconfigurable portion 524. Each of the plurality of dynamic reconfigurable portions can be dynamically reconfigured to one or more test and measurement devices based on the bitstreams loaded into the FPGA 512. The remainder of the FPGA 512 can correspond to the static reconfigurable portion of the FPGA 512. The static reconfigurable portion is also configured using a bitstream, however, unlike the plurality of dynamic reconfigurable portions, which can be reconfigured while the remainder of the FPGA 512 can continue operating, the static reconfigurable portions cannot be so reconfigured. The static reconfigurable portion can be configured initially during the deployment of the multi-instrument device 502. Thereafter, one or more of the dynamic reconfigurable portions can be reconfigured by loading bitstreams to the respective dynamic reconfigurable portions. The first dynamic reconfigurable portion 520 can be configured to function as a first test and measurement device (TM-1), the second dynamic reconfigurable portion 522 can be configured to function as a second test and measurement device (TM-2), and the n-th dynamic reconfigurable portion 524 can be configured to function as an n-th test and measurement device (TM-n). At least one of these test and measurement devices can be dynamically swapped with a different test and measurement device by loading the bitstream of the desired test and measurement device into the corresponding dynamic reconfigurable portion.

The FPGA 512 can include channel inputs 526 (also referred to as “input ports”) that can receive analog inputs. In some examples, the channel inputs 526 can have a coaxial connector (e.g., BNC) for connecting coaxial input cables. In some examples, the channel inputs 526 can include a ground connector and a signal connector for connecting any two-wire cable that can carry an input signal. The number of channel inputs 526 can be based on the number of input signals that the multi-instrument device 502 is designed to process. In some examples, the multi-instrument device 502 may have at least two channel inputs 526. In some other examples, the number of channel inputs 526 can vary between one and ten. In yet other examples, the number of channel inputs 526 can be equal to or greater than the number of the plurality of dynamic reconfigurable portions. The channel inputs 526 can be coupled with analog signal conditioning circuits 528. The analog signal conditioning circuits 528 can include impedance matching circuitry, such as, for example, a 50Ω termination resistance for impedance matching with coaxial input cables coupled to the channel inputs 526. In some examples, the analog signal conditioning circuits 528 can include passive or active filters and/or op-amps for processing the input signals provided by the channel inputs 526.

The outputs of the analog signal conditioning circuits 528 can be coupled with inputs of a plurality of analog-to-digital converters (ADCs). For example, the multi-instrument device 502 can include a plurality of ADCs 530 that can convert the analog signals provided to the channel inputs 526 into corresponding digital signals. The ADCs 530 can be configured by the one or more processors 510. For example, the one or more processors 510 can set or control at least one of the sampling rate, the mode, anti-aliasing filter ON/OFF, gain, DC offset, phase adjustment, etc., of the ADCs 530. In some instances, where two or more channel inputs 526 are connected to the same input signal, the respective ADCs 530 would have to be matched. In such instances, the one or more processors 510 can configure the ADCs 530 with the same parameter values. The one or more processors 510 can output configuration control signal to ADC control inputs 532. In some examples, the sampling rate of an ADC can be about 5 giga-samples/second (Gs/s) when only one channel input 526 is used, about 2.5 Gs/s when two channel inputs 526 are used, and 1.25 Gs/s when four channel inputs 526 are used. The above listed sampling rates are only examples, and sampling rates that are greater than or less than the ones listed above also can be implemented. The ADCs 530 can output an a-bit output that digitally encodes the value of the analog input signal at the sampling rate. In some examples, the value of a can be between (inclusive) 8 and 64, however these values are not limiting, and can be based on the specific implementations. The multi-instrument device 502 also can include at least one external trigger input 534.

The outputs of the ADCs 530 and the at least one external trigger input 534 can be consolidated into an input bus 516. The input bus 516 can be k-bits wide, and can include, in addition to the outputs of the ADCs 530, output of the output-to-input multiplexer 536. The input bus 516 can be coupled with each of the plurality of dynamic reconfigurable portions. That is, the input bus 516 is coupled with the first dynamic reconfigurable portion 520, the second dynamic reconfigurable portion 522, and the n-th dynamic reconfigurable portion 524. As a result, each dynamic reconfigurable portion can receive the outputs of all the ADCs 530, the at least one external trigger input 534, as well as the selected outputs of the plurality of dynamic reconfigurable portions via the output-to-input multiplexer 536. This allows the user to configure more than one test and measurement devices within the single FPGA that can process signals that are output by other test and measurement devices. The user can therefore create a test bench on the FPGA, where the test bench includes several test and measuring instruments that operate in conjunction to carry out complex data and signal processing within the same multi-instrument device 502.

At least one of the plurality of dynamic reconfigurable portions can output two types of outputs. For example, the first dynamic reconfigurable portion 520 outputs a first data stream 538 and one or more first channel streams 546. The first data stream 538 can represent, in some test and measurement devices, a near real-time digital data (or quantized data) output of the first test and measurement device TM-1. For example, if the first test and measurement device TM-1 were configured to operate as a signal generator, the first data stream 538 can represent a waveform output by the signal generator. As an example, the first data stream 538 can include a d-bit output every s seconds, where s can be equal to an inverse of the clock frequency provided to the first dynamic reconfigurable portion 520. The one or more first channel streams 546 can output data points corresponding to the output of the first test and measurement device TM-1. In particular, the one or more first channel streams 546 can include an array of d-bit output bits. In some instances, the array can include the d-bit output bits and corresponding time stamps. In some examples, the one or more first channel streams 546 can structured as maximum and/or minimum values of a sampled signal over a particular time window. This channel stream can be used by the client device 104 to display a shaded region on the display corresponding to the time window and the maximum and minimum values. Assuming again that he first test and measurement device TM-1 is a waveform generator, the one or more first channel streams 546 can include an array with a series of d-bit output with corresponding timestamps representing the waveform generated by the waveform generator. Similar to the first dynamic reconfigurable portion 520, the second dynamic reconfigurable portion 522 outputs a second data stream 540 and one or more second channel streams 548, and the n-th dynamic reconfigurable portion 524 outputs a n-th data stream 544 and one or more n-th channel streams 550.

The data stream outputs of the plurality of dynamic reconfigurable portions can be consolidated into an output bus 518. The output bus 518 can be m-bits wide and can include the plurality of d-bit data stream outputs. The multi-instrument device 502, in the static reconfigurable portion, can further include a set of output multiplexers 564 that can selectively provide the data streams output by the plurality of dynamic reconfigurable portions to channel outputs 562 (also referred to as “output ports”). The channel outputs 562 can be physical ports, similar to the channel inputs 526, and can include physical connectors to facilitate connecting cables to carry the analog signals provided to the channel outputs 562. The number of channel outputs can be based on the implementation. In some examples, the number of channel outputs 562 can equal to the number of channel inputs 526. In some examples, the number of channel outputs 562 can be between one and ten (inclusive). In yet other examples, the number of channel outputs 562 can be equal to or greater than the number of the plurality of dynamic reconfigurable portions. The output multiplexers 564 can be controlled by the one or more processors 510, which can determine the configuration of the output multiplexers 564 based on the type of test and measurement devices, the types of outputs, and the user configuration for the channel outputs 562. For example, if the user configures the multi-instrument device 502 to provide the output of the first dynamic reconfigurable portion 520 to a first of channel outputs 562, the one or more processors 510 can control the output multiplexer 564 corresponding to that output channel to select the first data stream 538 and output the first data stream to that channel output. In some examples, the output multiplexers 564 can be viewed as a data interface that outputs the data streams generated by the plurality of dynamic reconfigurable portions to the channel outputs 562. In some instances, the output multiplexers 564 can be configured such that data streams associated with each of the plurality of dynamic reconfigurable portions is provided to a separate physical output port, such as a channel output. That is, the one or more processors 510 can configure the output multiplexers 564 such that the data streams output by the plurality of dynamic reconfigurable portions is directed to separate channel outputs 562.

Before the data stream is output to the selected channel output, the data stream is converted from the digital domain to the analog domain. In particular, the multi-instrument device 502 can include a set of digital-to-analog converter (DACs) 558, where at least one DAC is associated with each channel output. The DACs 558 can convert the data stream output by the corresponding output multiplexer into an analog signal. The DACs 558 can be configured by the one or more processors 510. Specifically, the one or more processors 510 can configure parameters such as, for example, the sampling rate, reference voltage, etc. of the DACs 558. The multi-instrument device 502 also includes a set of signal conditioners 560 positioned before the channel outputs 562. The set of signal conditioners 560 can include filter, such as, for example, band-pass filters, to remove noise from the analog output signals.

The multi-instrument device 502 also includes a set of channel buffers associated with each of the plurality of dynamic reconfigurable portions. For example, the multi-instrument device 502 includes a first set of channel buffers 552 associated with the first dynamic reconfigurable portion 520, a second set of channel buffers 554 associated with the second dynamic reconfigurable portion 522, and a n-th set of channel buffers 556 associated with the n-th dynamic reconfigurable portion 524. Each set of channel buffers can include one or more channel buffers. The one or more first channel streams 546 output by the first dynamic reconfigurable portion 520 can be temporarily stored in the first set of channel buffers 552. Similarly, the one or more second channel streams 548 output by the second dynamic reconfigurable portion 522 can be temporarily stored in the second set of channel buffers 554, and the one or more n-th channel streams 550 can be temporarily stored in the n-th set of channel buffers 556.

The channel streams temporarily stored in the set of channel buffers can be transferred to the one or more memory units 514 via a channel stream data interface 566. The data interface 566 can include, for example, the Advanced eXtensible Interface (AXI). AXI is widely used as a bus architecture in the Xilinx FPGAs. However, other bus architectures or data interface architectures may also be used. In some examples, the channel streams temporarily stored in the set of channel buffers is transferred to the one or more memory units 514 when the channel buffers are full. In some other examples, the channel streams are transferred to the one or more memory units 514 after the size of the data in the channel buffers reaches a threshold value. The channel streams stored in the one or more memory units 514 can then be transferred to the client device 104 for display. In this manner, the output of each of the plurality of reconfigurable portions can be provided for display at the client device 104. The number of channel buffers in the set of channel buffers can depend upon the number of outputs generated by the corresponding test and measurement instrument. For example, again assuming that the first dynamic reconfigurable portion 520 is configured as a waveform generator, the number of channel buffers in the first set of channel buffers 552 can be equal to the number of waveforms generated by the waveform generator. In some instances, the number of channel buffers in the first set of channel buffers 552 can be fixed, but the number of channel buffers form the set of channel buffers utilized for temporarily storing the channel streams can be equal to the number of signals that are to be displayed on the client device 104. For example, if the waveform generator were to generate two waveforms, two channel buffers form the first set of channel buffers 552 can be utilized.

The channel streams stored in the one or more memory units 514 can be transferred to the client device via a data port or network port, where the multi-instrument device interface program 120 can display the received data points. The multi-instrument device interface program 120 can transform the received data points into an image frame that can displayed on the client device 104. In some examples, the one or more processors 510 can process the data points stored in the one or more memory units 514 to generate an image frame. The one or more processors 510 can run image processing programs that can generate the image frame based on the data points. The image processing programs can include, for example, Advanced Video Coding (AVC) based codecs. The one or more processors 510 can transmit the image frame to the client device 104 via the data port or the network port.

The multi-instrument device 502 further includes a set of device interconnects (or data buses) that directly provide the output data stream from one dynamic reconfigurable region to an input of another dynamic reconfigurable region. For example, the FPGA 512 can include a first device interconnect 568 that connects the output data streams from the first dynamic reconfigurable portion 520 to the data inputs of the second dynamic reconfigurable portion 522. A second device interconnect 570 can connect the output data streams from the second dynamic reconfigurable portion 522 to the subsequent dynamic reconfigurable portion. A n-th device interconnect 572 can connect the output of a preceding dynamic reconfigurable portion to the n-th dynamic reconfigurable portion 524. The device interconnects provide an additional conduit (in addition to the output-to-input multiplexer 536) to transfer data from outputs of dynamic reconfigurable portions to inputs of dynamic reconfigurable portions. While FIG. 5 shows that a device interconnect provides the output data stream from one dynamic reconfigurable portion to a single other dynamic reconfigurable portion, the device interconnect can be extended to other dynamic reconfigurable portions such that the output data stream from one dynamic reconfigurable portion is provided to more than one other dynamic reconfiguration portions.

The multi-instrument device 502 can further include a configuration data bus 574 that couples the one or more processors 510 with the plurality of dynamic reconfigurable portions. In particular, the one or more processors 510 can provide runtime configuration information to the test and measurement devices over the configuration data bus 574. The configuration data bus 574 can be coupled with each dynamic reconfigurable portion via a data bus shut-down logic 580. During reconfiguration of a dynamic reconfiguration portion, configuration registers therein may be inaccessible. If the one or more processors 510 were to attempt to access or write to these configuration registers, the one or more processors 510 may enter into a deadlock state. To avoid the deadlock state, the FPGA 512 can include data bus shut-down logic 580 that disables the connection between the configuration data bus 574 and the dynamic reconfigurable portion that is currently undergoing reconfiguration. The one or more processors 510 can enable/disable the desired data bus shut-down logic 580 by activating/deactivating shut-down logic control signals 576. The data bus shut-down logic 580 is generally provided as a core in the FPGA. For example, some Xilinx FPGAs can include a AXI shutdown manager core that can controlled by the one or more processors 510 to make interfaces between dynamic reconfiguration portions and static portions safe during reconfiguration of the dynamic reconfiguration portion.

The multi-instrument device 502 can also include one or more physical output ports for communicating data to and out of the multi-instrument device 502. For example, the multi-instrument device 502 can include a serial data port 582 and a network port 584. The serial data port 582 can include ports supporting USB, FireWire, PCI Express, etc. The serial data port 582 can facilitate connection with, for example, the client device 104. The network port 584 can include wired network ports, wireless network ports, or both. Wired network ports can include, for example, an Ethernet port. Wireless ports can include, for example, Bluetooth, WiFi, Zigbee, etc. The one or more processors 510, the one or more memory units 514, the serial data port 582, and the network port 584 can communicate over a data bus 586. During operation, the one or more processors 510 can transmit channel streams stored in the one or more memory units 514 to the client device via one or more of the serial port 582 and the network port 584. The network port 584 also can be utilized to communicate with the server 106 (FIGS. 1-4) to download bitstreams. The one or more processors 510 can utilize the network port 584 or the serial data port 582 to receive bitstreams from the client device 104. The bitstreams can be stored in the one or more memory units 514 until the bitstreams are loaded into the corresponding dynamic reconfigurable portion.

While not shown in FIG. 5, the multi-instrument device 502 can include one or more synchronization signal interconnects providing synchronization signals to two or more of the reconfigurable portions of the multi-instrument device 502. In particular, the synchronization signals can allow clock cycle synchronization between two or more of the test and measurement devices (TM-1, TM-2, . . . TM-n). The synchronization signal interconnects can be implemented in the static reconfigurable portions. In some examples, the synchronization signal can be selectively provided to two or more dynamic reconfigurable portions (i.e., the test and measurement devices (TM-1, TM-2, . . . TM-n)) to selectively synchronize those dynamic reconfigurable portions. The synchronization signals can arrive at the selected ones of the test and measurement devices at the same clock edge. For example, the synchronization signals can arrive at the selected test and measurement devices at the same rising clock edge. The one or more processors 510 can control which of the dynamic reconfigurable portions receive the synchronization signal. For example, the one or more processors 510 can control an enable logic (e.g., a logic gate) that when enabled, allows the synchronization signal to be provided to the dynamic configuration portion associated with the enable logic.

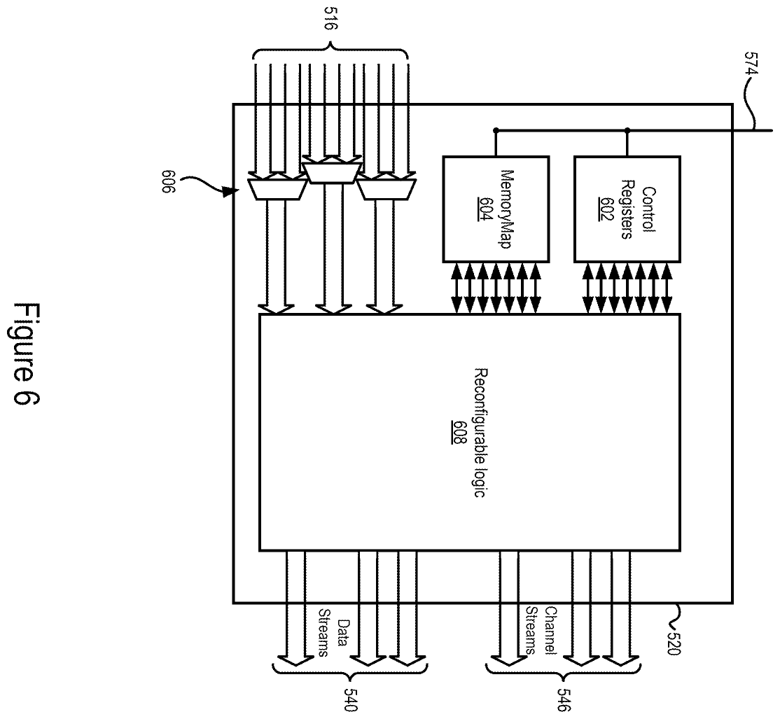

FIG. 6 shows an example block diagram of the first dynamic reconfigurable portion 520 shown in FIG. 5. The first dynamic reconfigurable portion 520 can include a set of control registers 602, at least one memory map 604 (or “at least one memory unit 604”), a plurality of multiplexers 606 and a reconfigurable logic 608. The control registers 602 can store configuration values specific to the test and measurement device configured in the first dynamic reconfigurable portion 520. For example, assuming the first dynamic reconfigurable portion 520 is configured to function as spectrum analyzer, the configuration registers 602 can store values for parameters such as start frequency and end frequency. In another example, assuming that the first dynamic reconfigurable portion 520 is configured to function as a PID controller, then the control registers 602 can store values for parameters such as filter coefficients. The memory map 604 also can store values of configuration parameters of the test and measurement device. In some instances, the storage capacity of the memory map 604 can be greater than the collective memory capacity of the configuration registers 602. The memory map 604 therefore can store additional data for the operation of the test and measurement device. For example, assuming the first dynamic reconfigurable portion 520 is configured to function as a waveform generator, the memory map 604 can store data related to a waveform generated by the waveform generator. In another example, assuming that the first dynamic reconfigurable portion 520 is configured to function as a spectrum analyzer, the memory map 604 can store data related to a windowing function.

The multiplexers 606 can receive data streams from the input bus 516, and select which ones of the data streams is provided to the reconfigurable logic 608. The one or more processors 510 can control the operation of the multiplexers 606 by storing the input selection configuration of the multiplexers in the control registers 602 or in the memory map 604. The outputs of the reconfigurable logic 608 can include the one or more first channel streams 546 and the first data stream 538. The reconfigurable logic 608 can include several logical blocks such as, for example, look up tables, flip-flops, block random access memory (RAM), digital signal processor (DSP) blocks, etc. The one or more processors 510 can use the bitstream to configure these logical blocks in the manner desired to function as a test and measurement device.

It should be noted that for most FPGAs that support partial reconfiguration, the FPGAs include proprietary processing logic included by the manufacturer of the FPGAs that facilitates the loading of the bitstreams onto the dynamic reconfigurable portions and the static reconfigurable portions and facilitates the management of the reconfigurable portions in general. For example, the Xilinx family of PR FPGAs include Partial Reconfiguration Controller (PRC) core that provides management functions for PR designs. The one or more processors 510, to reconfigure a portion of the FPGA can send the desired bitstream to the processing logic on the FPGA and instruct the processing logic to execute the reconfiguration operation. As such, the one or more processors 510 may not directly load the bitstream onto the dynamic reconfigurable portions. The procedures for interfacing with the processing logic on the FPGA can be specific to the FPGA manufacturer but are typically well documented by the manufacturer. To that end, a person skilled in the art can readily configure the one or more processors 510 to communicate with the processing logic of the FPGA.

Implementations of the subject matter and the operations described in this specification can be implemented in digital electronic circuitry, or in computer software embodied on a tangible medium, firmware, or hardware, including the structures disclosed in this specification and their structural equivalents, or in combinations of one or more of them. Implementations of the subject matter described in this specification can be implemented as one or more computer programs, i.e., one or more components of computer program instructions, encoded on computer storage medium for execution by, or to control the operation of, data processing apparatus. The program instructions can be encoded on an artificially-generated propagated signal, e.g., a machine-generated electrical, optical, or electromagnetic signal that is generated to encode information for transmission to suitable receiver apparatus for execution by a data processing apparatus. A computer storage medium can be, or be included in, a computer-readable storage device, a computer-readable storage substrate, a random or serial access memory array or device, or a combination of one or more of them. Moreover, while a computer storage medium is not a propagated signal, a computer storage medium can include a source or destination of computer program instructions encoded in an artificially-generated propagated signal. The computer storage medium can also be, or be included in, one or more separate physical components or media (e.g., multiple CDs, disks, or other storage devices).

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

1. A system, comprising:
a multi-instrument device including:
a static reconfigurable portion,
a plurality of dynamic reconfigurable portions, each of the plurality of dynamic reconfigurable portions configured as a test and measurement device, and
a controller, coupled with the static reconfigurable portion and the plurality of dynamic reconfigurable portions, configured to:
process at least one bitstream to reconfigure at least one of the plurality of dynamic reconfigurable portions as a test and measurement device; and
a server including:
memory configured to store the at least one bitstream, and
at least one processor configured to:
receive a request from the multi-instrument device for providing the at least one bitstream; and
responsive to the request, retrieve the at least one bitstream from the memory and transmit at least a portion of the at least one bitstream to the multi-instrument device.

2. The system of claim 1, wherein the multi-instrument device is configured to:
receive a request from a user device to load a desired test and measurement device, and
responsive to the request from the user device, communicate the request to the server for providing the at least one bitstream corresponding to the desired test and measurement device.

3. The system of claim 1, wherein the request for providing the at least one bitstream is a first request, wherein the at least one bitstream is a first at least one bitstream, wherein the at least one processor is configured to:
receive a second request for providing a second at least one bitstream, and
responsive to the second request, retrieve a second at least one bitstream from the memory and transmit the second at least one bitstream to the multi-instrument device; and
wherein the controller is configured to:
based on the second at least one bitstream, reconfigure at least one of the plurality of dynamic reconfigurable portions from one test and measurement device to another test and measurement device.

4. The system of claim 1, wherein the multi-instrument device further includes:
a data interface configured to output a data stream associated with each of the plurality of dynamic reconfigurable portions to a separate physical output port.

5. The system of claim 1, wherein the multi-instrument device further includes:
a data interface configured to output a data stream associated with each of the plurality of dynamic reconfigurable portions to at least one of a serial data port or a network port.

6. The system of claim 1, wherein the static reconfigurable portion includes at least one data bus configured to carry signals from at least one dynamic reconfigurable portion of the plurality of dynamic reconfigurable portions to at least one another dynamic reconfigurable portion of the plurality of dynamic reconfigurable portions.

7. The system of claim 1, wherein the static reconfigurable portion includes at least one multiplexer having inputs coupled with outputs of the plurality of dynamic reconfigurable portions, and at least one output coupled with an input of at least one dynamic reconfigurable portion of the plurality of dynamic reconfigurable portions, wherein the controller is configured to control the at least one multiplexer to allow at least one of the outputs of the plurality of dynamic reconfigurable portions to be provided to the input of the at least one dynamic reconfigurable portion of the plurality of dynamic reconfigurable portions.

8. The system of claim 7, wherein at least one output of the plurality of dynamic reconfigurable portions provides a data stream representing a quantized near real-time analog signal.

9. The system of claim 1, wherein the static reconfigurable portion includes:
at least one channel buffer coupled with at least one dynamic reconfigurable portion of the plurality of dynamic reconfigurable portions, each of the at least one channel buffer coupled with a channel output of a corresponding one of the plurality of dynamic reconfigurable portions, the at least one channel buffer configured to buffer a channel data stream output by the channel output and provide a buffered channel data stream to a memory of the multi-instrument device.

10. The system of claim 9, wherein the controller is configured to process the buffered channel data stream stored in the memory of the multi-instrument device to generate an output channel buffer data, and provide the output channel buffer data to one or more output ports of the multi-instrument device.

11. The system of claim 10, wherein the output channel buffer data is an image frame.

12. The system of claim 11, wherein channel data streams of at least one channel buffer coupled with each dynamic reconfigurable portion of the plurality of dynamic reconfigurable portions are stored into the memory of the multi-instrument device.

13. The system of claim 12, wherein the controller is configured to output the channel data streams to the one or more output ports of the multi-instrument device.

14. The system of claim 1, wherein at least one dynamic reconfigurable portion of the plurality of dynamic reconfigurable portions includes:
at least one control register coupled with the controller via a control bus, and
at least one memory unit coupled with the controller via the control bus,
wherein the at least one control register and the at least one memory unit store configuration data received from the controller and wherein the at least one memory unit is larger in size than the at least one control register.

15. The system of claim 1, wherein at least one dynamic reconfigurable portion of the plurality of dynamic reconfigurable portions includes:
at least one multiplexer, at least one input of which is coupled with data stream outputs of one or more other dynamic reconfigurable portions of the plurality of dynamic reconfigurable portions, and
at least one processor, at least one input of which is coupled with at least output of the at least one multiplexer.

16. The system of claim 2, further comprising:
the user device communicably coupled with the multi-instrument device and communicably coupled with the server, the user device configured to send a request to the server for providing another at least one bitstream, receive a transmission from the server including the another at least one bitstream, and transmit the another at least one bitstream to the multi-instrument device.

17. The system of claim 1, wherein the static reconfigurable portion includes at least one analog-to-digital converter (ADC) and at least one digital-to-analog converter (DAC), wherein each of the plurality of dynamic reconfigurable portions is selectively coupled with the at least one ADC and selectively coupled with the at least one DAC.

18. A multi-instrument device, comprising:
a static reconfigurable portion;
a plurality of dynamic reconfigurable portions, at least one of the plurality of dynamic reconfigurable portions configured as a test and measurement device; and
a controller, coupled with the static reconfigurable portion and the plurality of dynamic reconfigurable portions, configured to
reconfigure at least one of the plurality of dynamic reconfigurable portions as a test and measurement device based on at least one bitstream, and
reconfigure the static reconfigurable portion to provide data streams generated by each of the plurality of dynamic reconfigurable portions at a plurality of output ports,
wherein the controller is further configured to receive instructions to reconfigure at least one of the plurality of dynamic reconfigurable portions from a user device, and responsive to receiving instruction, request a server to provide the at least one bitstream.

19. The multi-instrument device of claim 18, wherein the plurality of output ports include a plurality of physical output ports, and wherein each physical output port of the plurality of physical output ports is selectively coupled to any one of the plurality of dynamic reconfigurable portions.

20. The multi-instrument device of claim 18, further comprising:
a plurality of input ports; and
a plurality of analog-to-digital converters (ADCs) coupled with the plurality of input ports,
wherein the static reconfigurable portion includes at least one input bus coupled with the plurality of ADCs and configured to selectively provide digital signals from each of the plurality of ADCs to each of the plurality of dynamic reconfigurable portions.

21. The multi-instrument device of claim 18, further comprising:
a plurality of output ports; and
a plurality of digital-to-analog converters (DACs) coupled with the plurality of output ports,
wherein the static reconfigurable portion includes at least one output bus coupled with the plurality of DACs and configured to selectively provide output signals from each of the plurality of dynamic reconfigurable portions to each of the plurality of DACs.

22. The multi-instrument device of claim 18, wherein the at least one bitstream is a first at least one bitstream, wherein the at least one controller is configured to:
receive a second at least one bitstream over a data interface, and
reconfigure the at least one of the plurality of dynamic reconfigurable portions from one test and measurement device to another test and measurement device based on the second at least one bitstream.

23. The multi-instrument device of claim 18, further comprising:
an output interface configured to output a data stream associated with each of the plurality of dynamic reconfigurable portions to a separate physical output port.

24. The multi-instrument device of claim 18, further comprising:
a network interface configured to output a data stream associated with each of the plurality of dynamic reconfigurable portions to at least one of a serial data port or a network port.

25. The multi-instrument device of claim 18, wherein the static reconfigurable portion includes at least one data bus configured to carry signals from at least one dynamic reconfigurable portion of the plurality of dynamic reconfigurable portions to at least one another dynamic reconfigurable portion of the plurality of dynamic reconfigurable portions.

26. The multi-instrument device of claim 18, wherein the static reconfigurable portion includes at least one multiplexer having inputs coupled with outputs of the plurality of dynamic reconfigurable portions, and at least one output coupled with an input of at least one dynamic reconfigurable portion of the plurality of dynamic reconfigurable portions, wherein the controller is configured to control the at least one multiplexer to allow at least one of the outputs of the plurality of dynamic reconfigurable portions to be provided to the input of the at least one dynamic reconfigurable portion of the plurality of dynamic reconfigurable portions.

27. The multi-instrument device of claim 18, wherein at least one output of the plurality of dynamic reconfigurable portions provides a data stream representing a quantized near real-time analog signal.

28. The multi-instrument device of claim 18, wherein the static reconfigurable portion includes:
at least one channel buffer coupled with at least one dynamic reconfigurable portion of the plurality of dynamic reconfigurable portions, each of the at least one channel buffer coupled with a channel output of a corresponding one of the plurality of dynamic reconfigurable portions, the at least one channel buffer configured to buffer a channel data stream output by the channel output and provide a buffered channel data stream to a memory.

29. The multi-instrument device of claim 28, wherein the controller is configured to process the buffered channel data stream stored in the memory to generate output channel buffer data, and provide the output channel buffer data to one or more output ports of the multi-instrument device.

30. The multi-instrument device of claim 29, wherein the output channel buffer data is an image frame.

31. The multi-instrument device of claim 29, wherein channel data streams of at least one channel buffer coupled with each dynamic reconfigurable portion of the plurality of dynamic reconfigurable portions are stored into the memory.

32. The multi-instrument device of claim 31, wherein the controller is configured to output the channel data streams to one or more output ports of the multi-instrument device.

33. The multi-instrument device of claim 18, wherein the at least one dynamic reconfigurable portion of the plurality of dynamic reconfigurable portions includes:
at least one control register coupled with the controller via a control bus, and
at least one memory unit coupled with the controller via the control bus,
wherein the at least one control register and the at least one memory unit store configuration data received from the controller and wherein the at least one memory unit is larger in size than the at least one control register.

34. The multi-instrument device of claim 18, wherein the at least one dynamic reconfigurable portion of the plurality of dynamic reconfigurable portions includes:
at least one multiplexer, at least one input of which is coupled with data stream outputs of one or more other dynamic reconfigurable portions of the plurality of dynamic reconfigurable portions, and
at least one processor, at least one input of which is coupled with at least output of the at least one multiplexer.

35. The multi-instrument device of claim 18, further comprising:
a memory interface coupled with a memory storage storing the least one bitstream received from the server,
wherein the controller is configured to access the at least one bitstream from the memory storage over the memory interface.

36. The multi-instrument device of claim 35, wherein the controller is configured to:
receive additional instructions for reconfiguring the at least one of the plurality of dynamic reconfigurable portions from the user device via an interface, and
responsive to the receipt of the additional instructions, access another at least on bitstream from the memory storage over the memory interface.

37. The multi-instrument device of claim 18, further comprising:
at least one digital input port,
wherein the static reconfigurable portion includes at least one input bus coupled with the at least one digital input port and configured to selectively provide digital signals from each of the at least one digital input port to each of the plurality of dynamic reconfigurable portions.

38. The multi-instrument device of claim 18, further comprising:
at least one digital output port,
wherein the static reconfigurable portion includes at least one output bus coupled with the at least one digital output and configured to selectively provide output signals from each of the plurality of dynamic reconfigurable portions to each of the at least one digital output port.
